(19) United States
(12) Patent Application Publication
(10) Pub. No.: US 2004/0131194 A1
(43) Pub. Date: Jul. 8, 2004

(54) Process and device for testing the functionality of loudspeakers

(76) Inventors: Andreas Gruhle, Ulm (DE); Host Kibbel, Erbach (DE); Marco Zeuner, Stuttgart (DE)

Correspondence Address: PENDORF & CUTLIFF, 5111 Memorial Highway, Tampa, FL, 33634-7356, US

(21) Appl. No.: 10/692,558

(22) Filed: Oct. 24, 2003

(30) Foreign Application Priority Data
Oct. 24, 2002 (DE) 102 49 495.9-35.

(51) Int. Cl. H04R 29/00; G01R 1/00

(52) U.S. Cl. 381/59; 324/126

(57) ABSTRACT

The invention concerns a device and a process for testing for functionality of loudspeakers, in which the electro-magnetic alternating fields produced by the loudspeaker are received via an antenna, the received signals are evaluated for signal components in the transmission range of loudspeakers using a unit for analysis, and in the case of the existence of the functionality this is displayed using a display unit.

### BACKGROUND OF THE INVENTION

1. Field of the Invention

The invention concerns a device and a process for testing the functionality of loudspeakers.

2. Description of the Related Art

In U.S. Pat. No. 5,736,846 A1 a device is disclosed for testing the functionality of loudspeakers, wherein a sensor is located in the input area of the loudspeaker for detecting the alternating current via which the loudspeaker is driven. More specifically, appropriate sensors are provided both at the input as well as the output, and the detected signals are compared. By means of this comparison it can be determined whether there is a disruption in the lines going to the loudspeaker or, as the case may be, a broken electrical connection in the loudspeaker, or some other disruption.

Further, it is known to test the functionality of loudspeakers installed in a vehicle in the manner that a person conducts an audio test, which however results in a subjective evaluation and is associated with particularly lengthy test times. In appropriate manner it is also possible to carry out a test using an electronic tone analysis with appropriate microphone arrays and a subsequent evaluation unit. These systems have been found to be particularly expensive when they are intended to be suited for being able to selectively evaluate individual loudspeakers within a vehicle cabin from among a plurality of loudspeakers.

### SUMMARY OF THE INVENTION

The present invention is concerned with the task of providing a device and a process for testing the functionality of loudspeakers, which can be employed economically, and which make possible a selective indication regarding the functionality of installed loudspeakers in a vehicle cabin.

This task is solved by a device with the characteristics of patent claim 1 and a process with the characteristics of patent claim 15.

Advantageous embodiments and further developments are subject of the dependent claims.

The invention takes advantage of the fact that the sound waves produced in a loudspeaker from an electrical audio signal are produced by an electrical coil in a magnet. By this arrangement the membrane of the loudspeaker is caused to oscillate according to the audio signal, whereby sound is produced. The invention takes advantage of the magnetic wave field produced by the coil arrangement, also referred to as the alternating electromagnetic field, in such a manner, that the emitted alternating magnetic field is detected, analyzed and identified as the alternating field of the loudspeaker. By this recognition it can be determined, whether an interruption of the electrical input for the electrical audio signal or, as the case may be, an interruption of the electrical connections within the loudspeaker exists, so that the functionality of the loudspeaker does not result. If there is functionality, then by means of the inventive device or, as the case may be, according to the inventive process, the produced alternating field is detected and identified as the alternating field produced by the loudspeaker and indicated to the user of the device as an appropriate signal.

It has been found particularly advantageous that the electro-magnetic alternating fields produced by the loudspeaker have a very strong correlation to distance, so that it becomes possible in a simple manner to make a selective evaluation of the functionality of individual loudspeakers within a vehicle cabin of a vehicle having a series of different loudspeakers.

The invention further takes advantage thereof, that in the framework of the analysis of the received electro-magnetic alternating fields a testing occurs in that respect, whether signal components in the transmission area of the loudspeakers, in particular in the typical transmission area of loudspeakers, exists or not. By this limited consideration of the electro-magnetic frequency range of the received signals a reliable arrangement and reliable evaluation and judging of the signals results, so that a meaningful evaluation of the functionality of loudspeakers is made possible.

In accordance with the invention it is not the presence of pressure waves of the respective sound waves which is the basis of the examination for the evaluation of the functionality of loudspeakers, but rather the driver thereof which is used, or as the case may be, the direct stage prior to the electric-acoustic transformation of the audio signal. Accordingly, the sensor is not integrated into the input of the loudspeaker to detect the presence of the input electrical audio signals, but rather, it is the alternating magnetic fields, which are produced by the electric-acoustic transformation of the audio signals, which are used for evaluating the functionality of the loudspeaker. Therewith a very effective, economical and meaningful process and a corresponding device for evaluation and testing of the functionality of loudspeakers, in particular while installed condition, is provided. In particular, providing the possibility of testing the functionality of loudspeakers in the mounted condition is of particular significance, since the dismounting of loudspeakers in particular in a limited space, as exists in a vehicle cabin of a vehicle, is very difficult and expensive. This is not necessary in accordance with the present invention.

According to a preferred embodiment of the inventive device an antenna is provided for receiving the magnetic alternating fields, which exhibits one or more receiving coils, which are preferably oriented in different spatial directions. Thereby it becomes possible on the one hand, in particular by the selection of various receiver coils, to have differentiated evaluations regarding the mode and manner of the alternating fields, in particular with respect to their strength and their frequency, but also with respect to the varying orientations of the magnetic alternating fields. By the use of at least three receiver coils in various spatial directions independent of each other it is additionally made possible that continuously a significant proportion of the received magnetic alternating fields are detected by the antennas and supplied to the unit for analysis of the received signals. Thereby a very reliable function of the inventive device is ensured.

Beyond this, it has been found advantageous to provide an amplifier between the antenna and the unit for analysis for amplifying the received signals. With the aid of this amplifier it is assured that a sufficiently strong signal for analysis is available. Preferably, an amplifier with noise suppressor is employed, which is in particular free of noise, particularly in the range of audio frequencies, that is, essentially in the area of the transmission frequencies of the loudspeaker, which means in certain cases also in the ultra or infrasound range. The amplifier makes possible a particularly simple evaluation or, as the case may be, analysis of the received signal, which substantially simplifies the circuitry for analysis of received signals. Therewith it becomes possible to provide a very simple and cost effective device for testing of loudspeakers.

It has been found particularly advantageous to provide within the unit for analysis a filter element for filtering the received signals. This filter unit is preferably a band pass filter, which exhibits a throughput range corresponding to the transmission range of the loudspeaker. Thereby it is particularly ensured that non-relevant, interfering received electro-magnetic alternating fields do not disturb the analysis of the received signals. Thereby a reliable evaluation of the received signals with respect to the functionality of the loudspeaker is in particular made possible.

It has been found particularly useful to provide the filter unit with multiple switchable band pass filters with throughput ranges according to the transmission ranges of various different loudspeakers, so that with the aid of a simple switching of the band pass filters respectively one optimized analysis of the received signals is made possible. This has demonstrated itself to be particularly useful in the testing of the functionality of multiple loudspeakers, or of loudspeakers which are not spaced far apart from each other. By the use of the switchable band pass filters it becomes possible to differentiate a midrange from a high tone or a bass loudspeaker, in the case that these are driven with varying audio frequencies, for example by a frequency dividing network or diplexer. Beyond this it is possible to test multiple loudspeakers, that is, loudspeakers with multiple electric-acoustic transformers, separately from each other. For example, it is made possible thereby to analyze the high tones separate from the bass, even when the high tone is connected with the membrane of the base and if a sympathetic audio signal in the base range oscillates along therewith. This type of loudspeaker can only be tested with difficulty by the conventional known functionality testers for loudspeakers which evaluate the acoustic signal. A reliable and meaningful evaluation is made possible by the inventive device.

Therein it has been found particularly useful to provide a filter with a throughput range of approximately 100 Hz to 10 kHz or from 100 Hz to 1 kHz, since this throughput range is used by the most conventional audio signals and in appropriate manner is covered at least partially by the transmission range of the loudspeaker. Thereby it is ensured that one unit for analysis with an individual filter with the above-mentioned throughput range makes possible one meaningful evaluation. This device has been found to be particularly simple and economical to produce.

It has been found to be particularly useful to supply the received signal to a logarithmic stage such that the analysis of the received signals can more meaningful and be received differentiated with respect to the strength of the received signals. For this, the received signal is preferably supplied to a semiconductor component, in particular a diode with logarithmic characteristic.

According to a different embodiment of the invention, the device is provided with an input for receiving an audio signal. The audio signal is therein the same as that which is being supplied to the loudspeaker being examined. In the analysis unit a correlation stage is provided, which correlates the received signal with the audio signal supplied at the input and thereby submits the signal to a further evaluation as to sufficient correlation. If a sufficient correlation is detected, then these signals are not subject to any further testing, whereby a selective evaluation of different received signals is made possible. Thereby an operation of the device in an environment which is complex due to the plurality of electro-magnetic transmitters is made possible.

It has been found particularly useful to provide the device with an output unit, which is in condition to provide an optical and/or acoustic signal in the case of a positive evaluation of the functionality of the loudspeaker. Thereby it has been found particularly useful to produce both an acoustic as well as an optical signal, since the device is operated in a vehicle internal space, in particular the framework of the completing of the vehicle in an environment with large ambient noise, so that here the acoustic signal is not to be trusted, wherein in less optimal positions, for example in the foot area, in which particularly preferably the base loudspeakers are provided, an optical signal is not easily recognized, such that there the acoustic signal is easier to detect. Therewith it becomes clear that in areas which are less suitable for the optical signal output it is the acoustic which has the advantage, and the reverse. This leads to a very reliable informing of the user regarding the functionality of the loudspeaker being examined.

Besides this, it has been found particularly advantageous to construct the device as a portable or hand carried device with a carryable housing. With the carryable housing all the components of the inventive device, including in particular the antenna, are integrated. The housing is preferably of such a design that it includes projections and recesses in such a manner that a comfortable and reliable gripping and holding of the device via the housing is made possible.

Besides this, it has been found particularly useful to provide the device, in particular in its carryable form, with an independent energy supply, particularly in the form of a battery or a fuel cell system for providing energy. Thereby a simple manipulation of the device is made possible in the respect that no cabling is necessary for supplying energy to the device. Therewith a flexiable employment of the inventive device in various environments, in particular in the various areas of a vehicle internal space, is made possible in simple manner. An impeding of the user by unnecessary cabling can be avoided thereby. Thereby a simple to manipulate, light, portable device for testing the functionality of loudspeakers is provided.

According to a different embodiment of the invention there is realized a process for testing of loudspeakers for functionality, wherein the electro-magnetic alternating fields are detected via an antenna and analyzed with respect to whether these alternating fields are being produced by an electrical audio signal driven loudspeaker. Therein the signals received by the antenna are analyzed with a unit for analysis as to whether or not the received signals exhibit signal components in the transmission area of loudspeakers. If these signal components in the transmission range of loudspeakers are present and display a sufficiently strong signal, then it is concluded that the loudspeaker has functionality and this result is displayed by means of an optical and/or acoustic output unit.

In a particularly preferred embodiment the analysis is carried out via a correlation of the electrical audio signal supplied to the one loudspeaker against the received electro-magnetic signals, whereby interfering influences of other sources of electro-magnetic alternating fields can be reliably excluded.

According to an alternative embodiment of the inventive device the signal received by the antenna is subject to an analog/digital conversion and subsequently supplied to a digital signal processor. This digital signal processing makes possible the analysis of the digitized received signal with respect to signal components in the transmission range and makes possible the subsequent evaluation of the signal such that a reliable and meaningful information for functionality of the loudspeaker can be obtained. This inventive device is characterized by a very compact and economical construction, in particular in cases when the digital signal processing, in certain cases in combination with the A/D transformer, is a micro-controller, signal processor or ASIC. The digital signal processing makes it possible beyond this to conform the framework conditions of the signal analysis very flexibly to the external environment conditions, in particular the filter ranges, the threshold values, etc.

### BRIEF DESCRIPTION OF THE DRAWINGS

In the following the invention will be described in greater detail on the basis of an exemplary construction of an inventive device.

FIG. 1 shows an exemplary design of an inventive device.

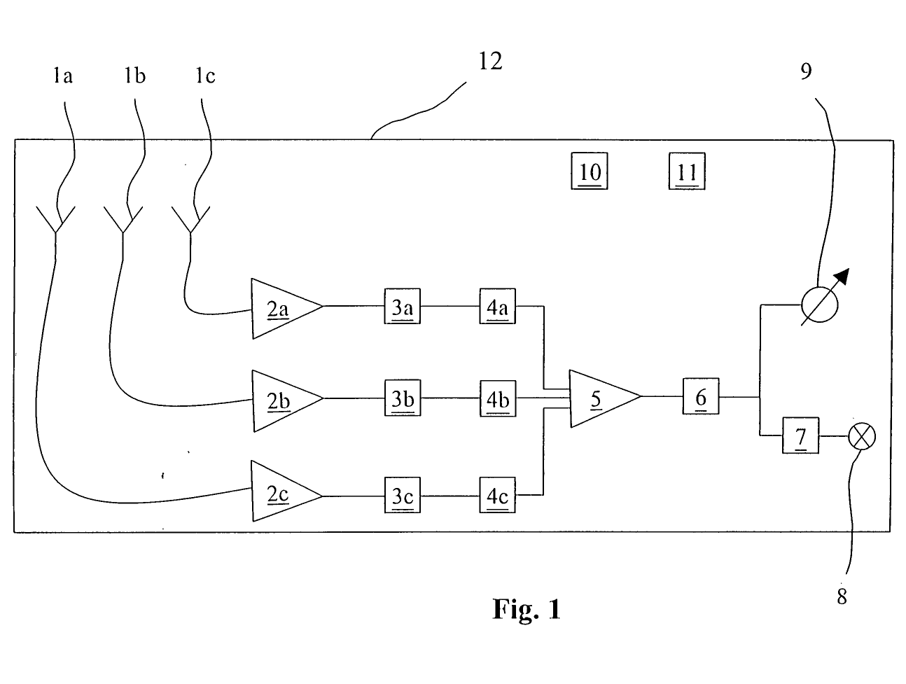

### DETAILED DESCRIPTION OF THE INVENTION

The device includes three antenna 1a, 1b, 1c, which are oriented in three different spatial directions. The antenna 1a, 1b, 1c are integrated in the housing 12 of the device. The electro-magnetic alternating fields are received by the antennas and supplied as alternating current signals to three amplifier stages 2a, 2b, 2c. These amplify the received signals and subsequently provide them to the filter stages 3a, 3b, 3c, which are band pass filters with a throughput range of 100 Hz through 10 kHz. This throughput range is so selected that it at least partially covers the conventional transmission range of the loudspeaker and additionally also the conventional frequency range of conventional audio signals. Thereby it is ensured that always a meaningful evaluation of the functionality of the loudspeaker can be achieved. The received amplified and filtered signals are subsequently rectified or demodulated with demodulation stages 4a, 4b, 4c and added or summed in 5. The signal which is rectified and logarithmic via a diode circuit 6 is supplied to a comparator 7. The comparator 7 compares the integrated signal with a predetermined threshold value. If the threshold value is exceeded, then the evaluation unit 8, which includes a beeper and a light diode as optical and acoustic signal sources, is activated. If the threshold is not exceeded, then no activation occurs and therewith no positive signal generation by means of the output unit 8 occurs. Therewith it is determined whether sufficient strength of electro-magnetic alternating fields in the output range with respect to the transmission range of the loudspeaker (SN) is present or not. If sufficient strength is present, then this is made the basis of a positive evaluation of the functionality of the loudspeaker. In addition, for more precise quantitative measurements an analog value can be read using a display 9 (analog or digital display).

Besides the above mentioned components there is additionally provided in the housing 12 of the device a control unit 10, which controls the other components of the device, in particular the presetting of the threshold value of the comparator 7, as well as turning on and turning off. Besides this, as the energy source for the device an independent energy supply 11 is provided, which may be a fuel cell system with hydrogen gas. This independent energy supply 11 makes it possible to bring the inventive device with the housing 12 into any desired location of a loudspeaker as a mobile flexible carryable device, without the distraction that the energy must be supplied by a cable.

By the particular type of the analysis and evaluation of the electro-magnetic alternating fields for detection of the functionality of loudspeakers a very meaningful information source is provided, which makes possible even under difficult conditions a reliable rapid and economic evaluation of the functionality of the loudspeakers. A requirement for the dismantling of the loudspeaker for the testing is no longer necessary when using the inventive device. The test can be carried out rapidly and very meaningfully.

1. Device for testing functionality of loudspeakers, thereby characterized, that it includes an antenna for receiving magnetic alternating fields, a unit for analysis of the received signals with respect to signal components in the transmission range of loudspeakers and an output unit for signaling the functionality.

2. Device according to claim 1, thereby characterized, that the antenna includes one or more receiver coils.

3. Device according to claim 2, thereby characterized, that the receiver coils are oriented in different spatial directions.

4. Device according to one of the preceding claims, thereby characterized, that between antenna and unit for analysis an amplifier is provided for amplifying the received signal.

5. Device according to one of the preceding claims, thereby characterized, that the unit for analysis includes a filter unit for filtering the received signals.

6. Device according to claim 5, thereby characterized, that the filter unit includes a band pass filter with a throughput range corresponding to the transmission range of the loudspeaker.

7. Device according to claim 5, thereby characterized, that the filter unit includes multiple switchable band pass filters with throughput ranges corresponding to the transmission ranges of different loudspeakers.

8. Device according to claim 5, 6 or 7, thereby characterized, that the filter unit includes a filter with a throughput range of approximately 100 Hz to 10 kHz.

9. Device according to one of the preceding claims, thereby characterized, that the unit for analysis is adapted for logarithmic evaluation of the received signals.

10. Device according to one of the preceding claims, thereby characterized, that it includes an input for receiving the audio signals supplied to the loudspeaker and that the unit for analysis is adapted for correlating the received signals with the supplied audio signals.

11. Device according to one of the preceding claims, thereby characterized, that the output unit is capable of providing an optical and/or acoustic signal.

12. Device according to one of the preceding claims, thereby characterized, that it includes a portable housing.

13. Device according to one of the preceding claims, thereby characterized, that it includes an independent energy supply, in particular in the form of a battery or a fuel cell system.

14. Device according to one of the preceding claims, thereby characterized, that an analog-digital converter is provided subsequent to the antenna, and that the unit for analysis of the received signal is a device for digital signal processing, in particular in the form of a micro-controller, signal processor or a ASIC.

15. Process for testing functionality of loudspeakers, thereby characterized, that the electro-magnetic alternating fields formed by the loudspeaker are received via an antenna, the received signals are evaluated for signal components in the transmission range of loudspeakers using a unit for analysis, and in the case of the existence of the functionality this is displayed using a display unit.
